(19) United States
(12) Patent Application Publication
(10) Pub. No.: US 2015/0021173 A1
(43) Pub. Date: Jan. 22, 2015

(54) SPUTTERING DEVICE

(71) Applicant: NITTO DENKO CORPORATION, Osaka (JP)

(72) Inventors: Tomotake Nashiki, Osaka (JP); Akira Hamada, Osaka (JP)

(73) Assignee: NITTO DENKO CORPORATION, Osaka (JP)

(21) Appl. No.: 14/331,382

(22) Filed: Jul. 15, 2014

(30) Foreign Application Priority Data
Jul. 19, 2013 (JP) 2013-150541

(51) Int. Cl. H01J 37/34

(52) U.S. Cl. CPC H01J 37/3411; H01J 2237/332
USPC 204/298.07

(57) ABSTRACT

At least two gas supply pipes are connected to one gas pipe in a sputtering device. The sputtering device includes: a plurality of gas supply pipes provided outside a plurality of walls for surrounding a target, a plurality of gas pipes, and a plurality of gas supply ports each provided on an inner surface of each of the plurality of walls. The plurality of gas supply ports are each disposed on a side farther away from a film depositing roll than a surface of the target. The sputtering device further includes a plurality of cooling pipes for cooling the walls.

### BACKGROUND OF THE INVENTION

1. Field of the Invention

The present invention relates to a sputtering device configured to form a thin layer on a long film.

2. Description of Related Art

A sputtering method is widely used as a method for forming a thin layer in vacuum. In the sputtering method, plasma of sputtering gas is generated by applying a voltage between a base substrate and a target with the base substrate kept at an anodic potential and the target kept at a cathodic potential in a sputtering gas such as a low-pressure argon gas. Sputtering gas ions in plasma strike the target, so that a constituent material of the target is driven out. The constituent material of the target, which is driven out, is deposited on the base substrate to form a thin layer.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is simultaneously supplied in addition to a sputtering gas such as argon. In the reactive sputtering method, a constituent material of a target, which is driven out, reacts with a reactive gas, so that an oxide of the constituent material of the target is deposited on a base substrate.

In a sputtering device, a target and a cathode are usually mechanically and electrically integrated. The base substrate and the target face each other with a predetermined distance therebetween. The sputtering gas and the reactive gas are usually supplied between the base substrate and the target. The sputtering gas and the reactive gas may be supplied separately, or may be supplied in mixture.

In a sputtering device which is a silicon wafer whose substrate has a diameter of about 100 mm to 300 mm, a target is generally a disk. In this case, a space between the substrate and the target is in a circular cylindrical shape. When the space is circular cylindrical-shaped, it is not difficult to unify space density distribution of a sputtering gas. Accordingly, such a sputtering device has few problems that the thickness and the features of a thin layer deposited on the substrate vary depending on the position thereof. As a result, in such a sputtering device, a supply structure for a sputtering gas or a reactive gas does not need a sophisticated structure.

However, when the base substrate is a long film, it is handled differently from the silicon wafer or the glass plate. It is impossible to form a sputtered layer over the whole of the long film at a time. Accordingly, the long film delivered from a supply roll is wound around a film depositing roll (also referred to as a can roll) by less than one round, and the film depositing roll is rotated to cause the long film to continuously run. A film is deposited on a portion of the long film which faces the target. The long film after completion of film deposition is wound around a storage roll.

The target needs to cover the entire width (for instance, 1.6 m) of the long film. Accordingly, the target seen from a side of the film depositing roll is typically an elongated rectangle with a long side of about 1.7 m and a short side of about 0.1 m. In this case, it is considerably difficult to unify space density distribution of a sputtering gas and a reactive gas. When the space density distribution of a sputtering gas and a reactive gas is irregular, for instance, in the case of a thin layer made of an indium-tin oxide (ITO), a problem that the thickness, sheet resistivity, and transmittance or the like of the thin layer vary in accordance with the position of the thin layer arises.

A sputtering gas and a reactive gas are consumed during sputtering. Evacuation capability of a vacuum pump and the amount of the sputtering gas and the reactive gas supplied are controlled while measuring partial pressures of the sputtering gas and the reactive gas to keep the partial pressures of the sputtering gas and the reactive gas at certain level.

A flow of a sputtering gas and a flow of a reactive gas from a plurality of gas supply ports to the vacuum pump are formed in a vacuum chamber of a reactive sputtering device. In the case of a reactive sputtering device of a long film, a space between the film depositing roll and the target is an elongated rectangle, resulting in complicated gas flows. This makes it difficult to unify space density distribution of the sputtering gas and the reactive gas. This has been a problem from the past.

For instance, in JP 2002-121664 A, a sputtering gas is introduced near a target and a reactive gas is introduced near a long film. As a result, a sputtering gas is considerably in a rich state near a target and a reactive gas is considerably in a rich state near the long film. This increases sputter efficiency and reactive efficiency between sputtered particles and the reactive gas as well.

JP 2002-121664 A discloses that walls with an opening on a side opposed to a film depositing roll are provided around a target to surround the target. A sputtering gas is introduced near the target inside the walls and a reactive gas is introduced near the long film. In JP 2002-121664 A, a sputtering gas introduction pipe is disposed inside the walls. The sputtering gas introduction pipe has a great number of gas supply ports disposed along a width direction of the target and respective gas supply ports discharge the sputtering gas between a cathode and the walls. In addition, a reaction gas introduction pipe is disposed near the long film wound around the film depositing roll. The reactive gas introduction pipe has a great number of gas supply ports in a width direction of the film depositing roll and the respective gas supply ports discharge the reactive gas toward the long film.

In JP 2002-121664 A, a sputtering gas is discharged between the cathode and the walls. Accordingly, the sputtering gas strikes the walls and the cathode to be diffused between the cathode and the walls, resulting in highly efficient supply of the sputtering gas near the target. In addition, a reactive gas is discharged near the long film, so that the reactive gas is supplied near the long film with high efficiency.

In a reactive sputtering device with a long film, uniformity of space density distribution of a sputtering gas and a reactive gas was improved by JP 2002-121664 A. However, it has been turned out from study of the inventors of the present invention that the reactive sputtering device described in JP 2002-121664 A has the following disadvantages:
(1) JP 2002-121664 A does not disclose a gas supply pipe for supplying a gas into a gas pipe.
(2) JP 2002-121664 A discloses that a sputtering gas introduction pipe is disposed inside walls. There are fears that flows of a gas may be disturbed by the sputtering gas introduction pipe.
(3) The walls described in JP 2002-121664 A are useful for controlling flows of a gas. There is, however, a possibility that the walls may be, thermally-deformed by thermal radiation from a film depositing roll and a target and heating by plasma. In the case where the walls are thermally-deformed, there are fears that the way of the flows of the gas may be changed.

### SUMMARY OF THE INVENTION

It is an object of the present invention to reduce irregularity of gas concentrations of a sputtering gas and a reactive gas in a width direction of a long film.

It is another object of the present invention to avoid flows of a sputtering gas and a reactive gas from being disturbed by a plurality of gas supply pipes and a plurality of gas pipes.

It is a still another object of the present invention to remove defects arising from the change of gas flows caused by thermal deformation of walls and blocking of a target by use of deformed walls or the like.

The summary of the present invention is described as below.

In a first preferred aspect, there is provided a sputtering device according to the present invention configured to form a thin layer on a long film conveyed along a surface of a film depositing roll. The sputtering device comprises: a vacuum chamber; and a vacuum pump for evacuating the vacuum chamber. A film depositing roll and a target facing the film depositing roll are provided in the vacuum chamber. The target is surrounded by a plurality of walls. Up to five sides of a cuboid-shaped target out of six sides of the target except for one side facing the film depositing roll may be surrounded by respective walls. A plurality of gas supply ports for supplying a gas in a target direction are open to inner surfaces of the plurality of walls. A plurality of gas supply pipes connected to the plurality of gas supply ports are provided outside the walls.

In a second preferred aspect of the sputtering device according to the present invention, the plurality of gas supply ports are connected to the plurality of gas supply pipes via a plurality of gas pipes.

In a third preferred aspect, the sputtering device according to the present invention further comprises a cooling system configured to cool the plurality of walls.

In a fourth preferred aspect of the sputtering device according to the present invention, the plurality of gas supply pipes are connected to each of the plurality of gas pipes.

In a fifth preferred aspect of the sputtering device according to the present invention, at least a part of each of the plurality of gas supply ports is disposed on a side farther away from the film depositing roll than a surface of the target.

In a sixth preferred aspect of the sputtering device according to the present invention, the plurality of gas supply ports each comprise: a plurality of gas supply ports for supplying a sputtering gas; and a plurality of gas supply ports for supplying a reactive gas. The plurality of gas supply ports for supplying a reactive gas are each provided at a position closer to the film depositing roll than each of the plurality of gas supply ports for supplying a sputtering gas. At least the plurality of gas supply ports for supplying a sputtering gas are each provided at a position farther away from the film depositing roll than the surface of the target.

In a seventh preferred aspect of the sputtering device according to the present invention, a sputtering gas is an argon gas and a reactive gas is an oxygen gas.

In an eighth preferred aspect of the sputtering device according to the present invention, an electrical potential of the plurality of walls differs from an electrical potential of the target.

In a ninth preferred aspect of the sputtering device according to the present invention, the cooling system configured to cool the walls is a cooling water piping closely attached to the walls. The walls are cooled by passing cooled water in the cooling water piping to prevent the walls from being overheated.

### ADVANTAGES OF THE INVENTION

First, according to the present invention, it is possible to reduce irregularity of gas concentrations of a sputtering gas and a reactive gas in a width direction by connecting a plurality of gas supply pipes to respective gas pipes of a sputtering gas and a reactive gas (For instance, two gas supply pipes are connected to one gas pipe).

Secondly, according to the present invention, it is possible to prevent flows of a sputtering gas and a reactive gas from being disturbed when a plurality of gas supply pipes and a plurality of gas pipes are installed outside the walls and a sputtering gas and a reactive gas are supplied from the gas supply ports provided on inner surfaces of the walls.

Thirdly, according to the present invention, it is possible to prevent the walls from being thermally deformed by forcibly cooling using a cooling system closely attached to the walls. This makes it possible to prevent defects, such as changes of gas flows caused by thermal deformation of the walls and blocking of the target by use of deformed walls.

For a full understanding of the present invention, reference should now be made to the following detailed description of the preferred embodiments of the invention as illustrated in the accompanying drawings.

### BRIEF DESCRIPTION OF THE DRAWINGS

FIG. 1 is a perspective view of a whole of a sputtering device of the present invention;

FIG. 2 is a perspective view showing a periphery of a target in the sputtering device of the present invention;

FIG. 3 is a cross-sectional view showing a periphery of the target and a film depositing roll in the sputtering device of the present invention; and

FIG. 4(a) is a schematic distribution graph of gas concentrations at the time when one gas supply pipe is connected to one gas pipe; and

FIG. 4(b) is a schematic distribution graph of gas concentrations at the time when two gas supply pipes are connected to one gas pipe.

### DESCRIPTION OF THE PREFERRED EMBODIMENTS

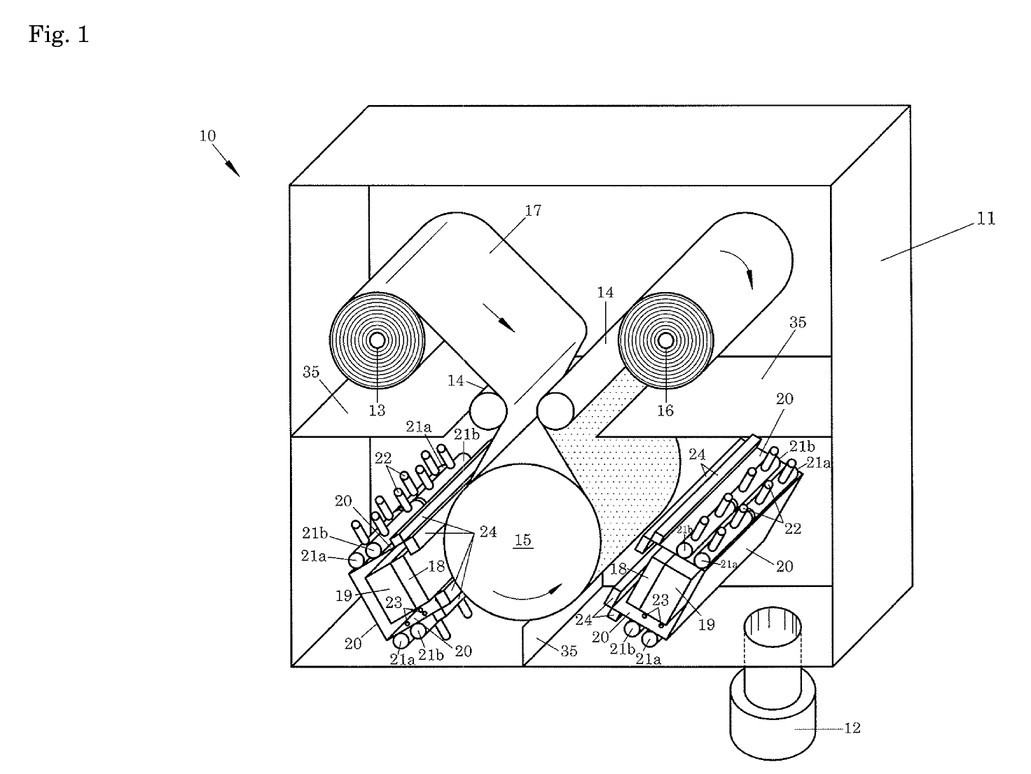

The preferred embodiments of the present invention will now be described with reference to FIGS. 1 to 4. Identical elements in the figure are designated with the same reference numerals.

FIG. 1 is a perspective view of a whole of one example of a sputtering device 10 of the present invention. The sputtering device 10 of the present invention includes a vacuum chamber 11, and a vacuum pump 12 for evacuating the vacuum chamber 11. A supply roll 13, a guide roll 14, a film depositing roll 15, and a storage roll 16 are provided in the vacuum chamber 11. A long film 17 is delivered from the supply roll 13, guided by the guide roll 14, wound around the film depositing roll 15 by less than one round, guided again by the guide roll 14, and stored in the storage roll 16. A target 18 faces the film depositing roll 15 with a predetermined distance therebetween. On the long film 17 continuously running over the film depositing roll 15, thin layers are formed at a position facing the target 18. While FIG. 1 illustrates two targets 18, the number of targets 18 is not limited. Since the kinds of a sputtering gas and a reactive gas and pressures vary depending on the targets 18, the vacuum chamber 11 is divided by walls 35 to prevent the sputtering gas and the reactive gas from entering an area of adjacent targets 18, supply roll 13, and a storage roll 16.

A homopolymer and a copolymer composed of polyethylene terephthalate, polybutylene terephthalate, polyamide, polyvinyl chloride, polycarbonate, polystylene, polypropylene, polyethylene or the like are typically used as a long film 17. The long film 17 may be either a single film or a laminated film. The thickness of the long film 17 is not limited, however, the thickness of the long film 17 is usually 6 μm to 250 μm.

In the sputtering device 10 of the present invention, plasma of a sputtering gas is generated by applying a voltage between the film depositing roll 15 and the target 18 with the film depositing roll 15 kept at an anodic potential and the target 18 kept at a cathodic potential in a sputtering gas such as a low-pressure argon gas. Sputtering gas ions in plasma strike the target 18, so that a constituent material of the target 18 is driven out. The constituent material of the target 18, which is driven out, is deposited on the long film 17 to form a thin layer.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is supplied in addition to a sputtering gas such as argon. In the reactive sputtering method, the constituent material of the target 18, which is driven out, reacts with a reactive gas, so that an oxide of the constituent material of the target 18 is deposited on the long film 17.

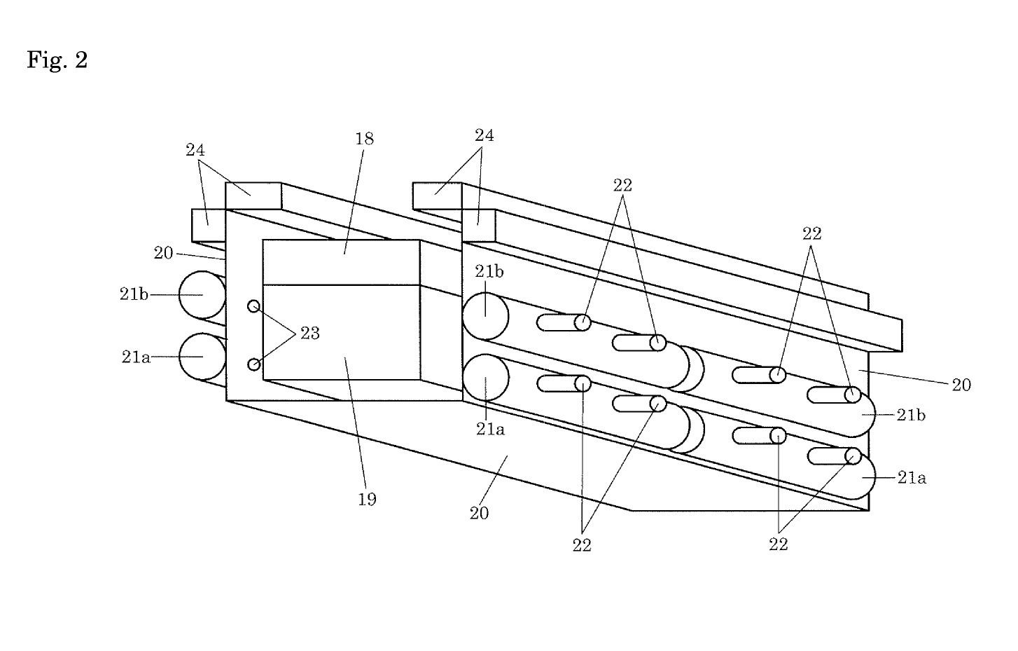

FIG. 2 is a perspective view showing a periphery of the target 18 in a sputtering device 10 of the present invention. The target 18 is in an elongated rectangle seen from the film depositing roll 15 side. A rear surface of the target 18 is screwed on a cathode 19 to be mechanically and electrically integrated with the cathode 19. An electrical potential of the target 18 and an electrical potential of the cathode 19 are equivalent.

At least two surfaces along log sides of the target 18 are surrounded by a plurality of walls 20. In FIG. 2, a surface along two long sides of the target 18 and a bottom of the target 18 are surrounded by the plurality of walls 20. Among six surfaces of the cuboid-shaped target 18, five surfaces may be surrounded by the walls 20 except for one surface facing the film depositing roll 15. The walls 20 have functions to prevent flows of a sputtering gas and a reactive gas from being disturbed.

When an electrical potential of each of the walls 20 is equivalent to the electrical potential of the target 18, there are fears that a constituent material of each of the walls 20 may be driven out because sputtering gas ions in plasma also strike the walls 20. Accordingly, the electrical potential of the walls 20 is set so as to be different from the electrical potential of the target 18. Generally, the electrical potential of each of the walls 20 is set higher than the electrical potential of the target 18. Since sputtering gas ions in plasma are cations, when the electrical potential of each of the walls 20 is higher than the electrical potential of the target 18, sputtering gas ions are more drawn to the target 18 than the walls 20.

While a material of each wall 20 is not limited, aluminum and stainless steel are suitable for the material of each of the walls 20. Cooling the walls 20 is easy because aluminum has a high thermal conductivity. Stainless steel is high in strength and is resistant to corrosion.

Each of the walls 20 preferably has a thickness of 2 mm to 10 mm. When the walls 20 each have a thickness of less than 2 mm, there are fears that the walls 20 may have insufficient strength. When the walls 20 each have a thickness of over 10 mm, there are fears that cooling of the walls 20 may be insufficient.

In the sputtering device 10 of the present invention, a plurality of gas pipes 21a for a sputtering gas and a plurality of gas pipes 21b for a reactive gas are separately disposed. In the sputtering device 10 of the present invention, one gas pipe 21a of sputtering gas is connected to at least two gas supply pipes 22. In addition, one gas pipe 21b of reactive gas is connected to at least two gas supply pipes 22. A sputtering gas and a reactive gas are each supplied to respective gas pipes 21a, 21b from respective gas supply pipes 22.

As shown in FIG. 2, the gas pipes 21a, 21b for supplying a sputtering gas and a reactive gas are installed outside the walls 20. When each of the walls 20 is also disposed on a lower side (bottom side) of the target 18, there is a possibility that the gas pipes 21a, 21b may be installed outside the lower side (bottom side) of each of the walls (not shown).

The gas supply ports 23 of sputtering gas and reactive gas penetrate through pipe walls of the gas pipes 21a, 21b and the walls 20 to open to inner surfaces of the walls 20. Sputtering gas and reactive gas come out of the gas supply ports 23 that have opened to the inner surfaces of the walls 20 in a direction of the target 18.

A sputtering gas and a reactive gas are supplied while evacuating the vacuum chamber 11 with the vacuum pump 12 during sputtering. Evacuation capability of the vacuum pump 12 and supplied amounts of the sputtering gas and the reactive gas are controlled while measuring partial pressures of the sputtering gas and the reactive gas to keep the partial pressures of the sputtering gas and the reactive gas at certain level. Generally, an argon gas is used as a sputtering gas and an oxygen gas is used as a reactive gas.

A plurality of cooling pipes 24 are closely in contact with the walls 20. The reason why the plurality of cooling pipes 24 are closely in contact with the walls 20 is to effectively transfer heat of the walls 20 to the cooling pipes 24. In the walls 20, a portion near the target 18 and plasma (an upward part in FIG. 2) is easily overheated. As shown in FIG. 2, therefore, the cooling pipes 24 are preferably provided on an upward portion of each of the walls 20 (a portion near the film depositing roll 15).

During sputtering, cooled water is flown to the cooling pipes 24 and the walls 20 are cooled to prevent the walls 20 from being thermally-deformed. A refrigerant to flow to the cooling pipes 24 is not limited to cooling water and the other refrigerants are usable. In place of the cooling pipes 24, a cooling system such as Peltier device may be used to electrically cool the walls 20.

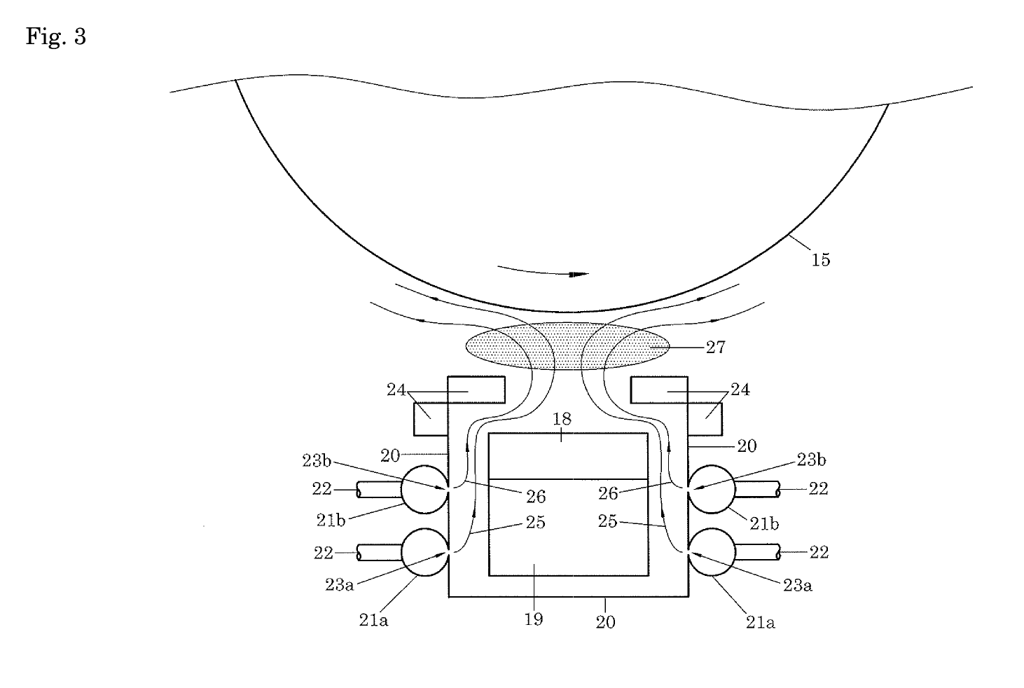

FIG. 3 is a cross-sectional view of a periphery of a target 18 and a film depositing roll 15 in the sputtering device 10 of the present invention. Gas pipes 21a are gas pipes for sputtering gas 25 and gas pipes 21b are gas pipes for reactive gas 26. Sputtering gas 25 comes out of a plurality of gas supply ports 23a and reactive gas 26 comes out of a plurality of gas supply ports 23b. Since the supplied amount of sputtering gas 25 is greater than the supplied amount of reactive gas 26, as shown in FIG. 3, the gas supply ports 23a for sputtering gas 25 are preferably disposed in a lower portion and the plurality of gas supply ports 23b for reactive gas 26 are preferably disposed in an upper portion. According to this configuration, reactive gas 26 smoothly flows because a little amount of reactive gas 26 is mixed with flows of a great amount of sputtering gas 25.

The positions of the gas supply ports 23a for sputtering gas 25 and the positions of the gas supply ports 23b for reactive gas 26 are not preferably opposite to FIG. 3. In the case of such a configuration, there are fears that the flows of reactive gas 26 may not smoothly flow due to a block by the flows of sputtering gas 25 because the supplied amount of reactive gas 26 is smaller than the supplied amount of sputtering gas 25.

As shown in FIG. 3, each of the gas supply ports 23a and the gas supply ports 23b is preferably disposed on a side farther away from the film depositing roll 15 (a lower side in FIG. 3) than a surface of the target 18. In the case of a configuration like FIG. 3, the flows of sputtering gas 25 and reactive gas 26 are aligned in a gap among the walls 20, the cathode 19, and the target 18 to form a layer flow of sputtering gas 25 and reactive gas 26 between the surface of the target 18 and the film depositing roll 15. In addition, it is possible to prevent defects that block the gas supply ports 23a, 23b caused by the deposition of atoms or molecules that are driven out from the target 18 around the gas supply ports 23a, 23b.

In the case where the gas supply ports 23a, 23b are each disposed on a side closer to the film depositing roll 15 than the surface of the target 18, sputtering gas 25 and reactive gas 26 that have been blown out flow into between the surface of the target 18 and the film depositing roll 15 in a turbulent flow state. In that case, the shape of plasma 27 formed between the surface of the target 18 and the film depositing roll 15 becomes unstable.

At least each of the gas supply ports 23a of sputtering gas 25 having a great supplied amount are preferably disposed on a side farther away from the film depositing roll 15 than the surface of the target 18. In the case of such a configuration, at least the flows of sputtering gas 25 are adjusted in the gap among the walls 20 and the cathode 19 and the target 18. This makes the shape of plasma 27 formed between the surface of the target 18 and the film depositing roll 15 stable.

As shown in FIG. 3, sputtering gas 25 and reactive gas 26 come out from respective gas supply ports 23a, 23b to the inside of the walls 20 and then drift upward in a gap among the walls 20, the cathode 19, and the target 18, and drift upward in a direction of the film depositing roll 15 from the upper opening of each of the walls 20. And sputtering gas 25 and reactive gas 26 strike the film depositing roll 15 and flow in the left and right to be finally discharged by the vacuum pump 12. In the sputtering device 10 of the present invention, the flows of sputtering gas 25 and reactive gas 26 are not easily disturbed because there are no gas supply pipes and gas pipes in the gap among the walls 20, the cathode 19 and the target 18.

When sputtering gas 25 flows out from an upper portion opening to come upward the target 18, a voltage is applied between the target 18 and the film depositing roll 15 to form plasma 27. In the sputtering device 10 of the present invention, the shape of plasma 27 to be formed is stable because there is little disturbance of the flows of sputtering gas 25. Accordingly, the sputter rate varies a little and changes of the layer thickness of a sputtered layer are few.

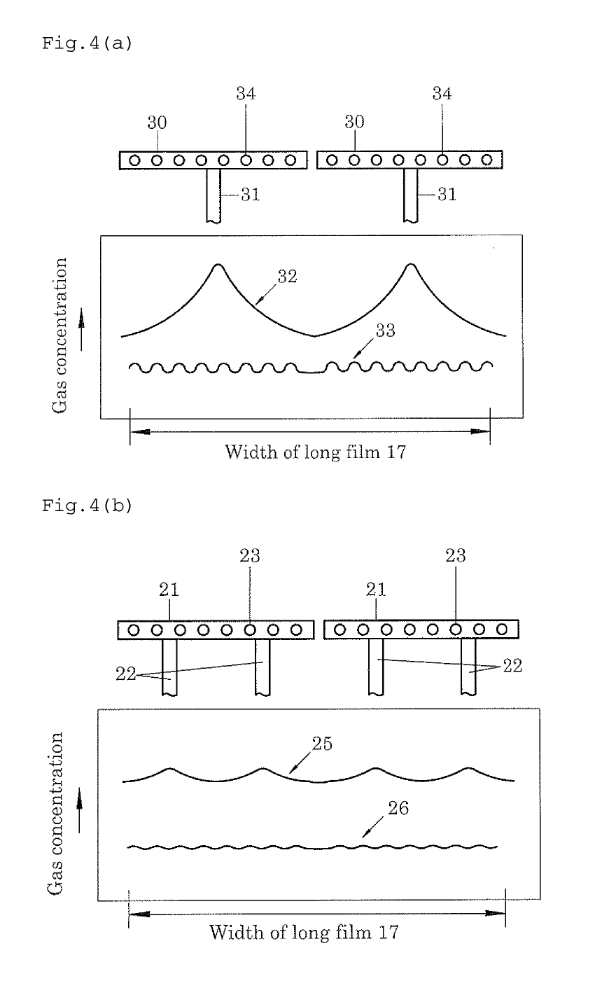

Next, improvements of gas concentration distribution in a width direction of a long film will now be described in detail. FIG. 4(a) is a schematic distribution graph of gas concentrations of sputtering gas 32 and reactive gas 33 at the time when one gas pipe 30 is connected to one gas supply pipe 31. FIG. 4(b) is a schematic distribution graph of gas concentrations of sputtering gas 25 and reactive gas 26 at the time when two gas supply pipes 22 are connected to one gas pipe 21. A horizontal axis of each graph represents the width of the long film 17.

In FIGS. 4(a) and 4(b), two gas pipes 30, 21 are arranged in series in a width direction of the long film 17. A vertical axis of each graph represents gas concentrations of sputtering gas 32, 25 and reactive gas 33, 26. Although the vertical axis of each graph is any measure, measures of vertical axes in FIGS. 4(a) and 4(b) are equal.

As shown in FIG. 4(a), when one gas supply pipe 31 is connected to one gas pipe 30, gas concentrations of sputtering gas 32 and reactive gas 33 greatly vary in a width direction of gas concentrations. Specifically, there is great variability in a width direction of gas concentrations of sputtering gas 32. The reason why there is great variability in gas concentrations of sputtering gas 32 is that sputtering gas 32 in a width direction has a high pressure and a great amount of blowing out, so that there is a big difference of gas pressures between the gas supply ports 34 near the center of the gas supply pipes 31 and end portions of the gas supply ports 34 from the gas supply pipes 31.

As shown in FIG. 4(b), when two gas supply pipes 22 are connected to one gas pipe 21, gas concentrations of sputtering gas 25 and reactive gas 26 in the width direction become less variable. Particularly, gas concentrations of sputtering gas 25 in the width direction become less variable significantly. The reason why gas concentrations of sputtering gas 25 in the width direction become less variable than FIG. 4(a) is that the difference of gas pressures of one gas supply ports 23 near the gas supply pipe 22 between the other gas supply port 23 away from the gas supply pipe 22 is reduced by increasing the gas supply pipes 22 by two pipes.

The number of the gas supply pipes 22 connected to one gas pipe 21 is not limited to two but may be three or more. The more amounts of the gas supply pipes 22 increase, the less gas concentrations of sputtering gas 25 and reactive gas 26 in the width direction have variability.

As shown in FIG. 4(b), in the sputtering device of the present invention, gas concentrations of sputtering gas 25 and reactive gas 26 have small variability in the width direction, so that density of plasma 27 has small variability in the width direction. As a result, when a thin layer of indium-tin oxide (ITO) has been typically formed, there is small variability in layer thickness, area resistivity, transmittance or the like in the width direction.

### INDUSTRIAL APPLICABILITY

The sputtering device of the present invention is useful for forming a thin layer, particularly, a transparent conductive layer of indium-tin-oxide (ITO) or the like, on a long film.

This application claims priority from Japanese Patent Application No. 2013-150541, which is incorporated herein by reference.

There has thus been shown and described a novel sputtering device which fulfills all the objects and advantages sought therefor. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A sputtering device comprising:
a vacuum chamber;
a vacuum pump for evacuating the vacuum chamber;
a film depositing roll provided in the vacuum chamber;
a target facing the film depositing roll;
a plurality of walls for surrounding the target;
a plurality of gas supply ports for supplying a gas in a target direction are open to inner surfaces of the plurality of walls; and
a plurality of gas supply pipes connected to the plurality of gas supply ports, the plurality of gas supply pipes being provided outside the walls,
a thin layer is formed on a long film conveyed along a surface of the film depositing roll.

2. The sputtering device according to claim 1, wherein the plurality of gas supply ports are connected to the plurality of gas supply pipes via a plurality of gas pipes.

3. The sputtering device according to claim 1, further comprising a cooling system configured to cool the plurality of walls.

4. The sputtering device according to claim 2, wherein the plurality of gas supply pipes are connected to each of the plurality of gas pipes.

5. The sputtering device according to claim 1, wherein at least a part of each of the plurality of gas supply ports is disposed on a side farther away from the film depositing roll than a surface of the target.

6. The sputtering device according to claim 1, wherein the plurality of gas supply ports each comprise: a plurality of gas supply ports for supplying a sputtering gas; and a plurality of gas supply ports for supplying a reactive gas,
the plurality of gas supply ports for supplying the reactive gas are each provided at a position closer to the film depositing roll than each of the plurality of gas supply ports for supplying the sputtering gas, and
at least the plurality of gas supply ports for supplying the sputtering gas are each provided at a position farther away from the film depositing roll than the surface of the target.

7. The sputtering device according to claim 6, wherein a sputtering gas is an argon gas and a reactive gas is an oxygen gas.

8. The sputtering device according to claim 1, wherein an electrical potential of the plurality of walls differs from an electrical potential of the target.

9. The sputtering device according to claim 3, wherein the cooling system configured to cool the walls is a cooling water piping closely attached to the walls.
